(19) United States
(12) Patent Application Publication
(10) Pub. No.: US 2016/0020246 A1
(43) Pub. Date: Jan. 21, 2016

(54) METHOD FOR FABRICATING CMOS IMAGE SENSORS AND SURFACE TREATING PROCESS THEREOF

(71) Applicant: UNITED MICROELECTRONICS CORPORATION, Hsinchu (TW)

(72) Inventors: Shou-Guo WANG, Nanjing (CN); Boon-Tiong Neo, Singapore (SG); Han-Chuan Fang, Singapore (SG)

(73) Assignee: UNITED MICROELECTRONICS CORPORATION, Hsinchu (TW)

(21) Appl. No.: 14/332,346

(22) Filed: Jul. 15, 2014

(51) Int. Cl. H01L 27/146; H01L 21/306; H01L 21/02; H01L 21/762

(52) U.S. Cl. CPC H01L 27/14689; H01L 27/1463; H01L 27/14643; H01L 21/76224; H01L 21/30625; H01L 21/0206

(57) ABSTRACT

The present invention provides a method for fabricating a CMOS image sensor including a plurality of steps. Firstly, a substrate is provided. Then, a pixel region covering most of the substrate and a logic circuit region on a periphery of the substrate are formed. After that, at least one trench is formed in the pixel region. Next, a deposition process is performed to fill the at least one trench and cover the pixel region. Then, a planarization process is performed to expose a surface of the pixel region. A first treatment on the exposed surface of the pixel region is next performed by applying a first cleaning solution including hydrogen fluoride (HF) and ethylene glycol (EG). Besides, an amount of HF is lesser than that of EG.

### FIELD OF THE INVENTION

The present invention provides a method for fabricating a semiconductor structure and a surface treating process thereof, especially to a method for fabricating a semiconductor structure for a CMOS image sensor and a surface treating process thereof

### BACKGROUND OF THE INVENTION

With the miniaturization trends of the semiconductor devices, a cleaning process has become an important issue to improve the device performance in the fabrication of the semiconductor devices. A cleaning process had been commonly used during manufacturing process to remove unwanted particles and residues remained on a surface of a semiconductor structure before subsequent processing. For example, in a CMOS image sensor manufacturing process, if some particles are found to be remaining on a pixel region surface without removing these particles before the formation of the next layer, these particles may impair the performance and reliability of the CMOS image sensor. Therefore, it is desire to improve the fabrication process of the CMOS image sensor for better performance and reliability.

### SUMMARY OF THE INVENTION

In accordance with an aspect, the present invention provides a method for fabricating a CMOS image sensor including a plurality of steps. Firstly, a substrate is provided. Then, a pixel region covering most of the substrate and a logic circuit region on a periphery of the substrate are defined. After that, at least one trench is formed in the pixel region. Next, a deposition process is performed to fill the at least one trench and cover the pixel region. Then, a planarization process is performed to expose a surface of the pixel region. A first treatment on the exposed surface of the pixel region is next performed by applying a first cleaning solution including hydrogen fluoride (HF) and ethylene glycol (EG). Besides, an amount of HF is lesser than that of EG.

In one embodiment of the present invention, a ratio of hydrogen fluoride (HF) to ethylene glycol (EG) is about 1:20 to about 1:50.

In one embodiment of the present invention, a weight percentage of ethylene glycol (EG) is about 1% to about 20%, and a weight percentage of hydrogen fluoride (HF) is about 1% to about 50%.

In one embodiment of the present invention, the trench in the pixel region is a deep trench and has a width larger than 0.5 um.

In one embodiment of the present invention, the exposed surface of the pixel region includes a nitride layer.

In one embodiment of the present invention, after the first treatment is performed, the method further includes a step of performing a second treatment on the exposed surface of the pixel region by applying a second cleaning solution, which contains ammonium hydroxide (NH₄OH).

In one embodiment of the present invention, a weight percentage of ammonium hydroxide (NH₄OH) is about 10% to about 50%.

In one embodiment of the present invention, the second cleaning solution further includes ethylene glycol (EG), and a ratio of ammonium hydroxide (NH₄OH) to ethylene glycol (EG) is about 1:10 to about 1:50 in the second cleaning solution.

In one embodiment of the present invention, the method further includes a step of forming at least one shallow trench in the logic circuit region. The deposition process is performed to further fill the at least one shallow trench, the planarization process is performed to further expose a surface of the logic circuit region, and the first treatment is performed further on the exposed surface of the logic circuit region.

In one embodiment of the present invention, the shallow trench has a width less than 0.2 um.

In accordance with another aspect, the present invention provides a method for treating a surface of a semiconductor structure including a step of applying to the surface of the semiconductor structure a first cleaning solution containing essentially hydrogen fluoride (HF) and ethylene glycol (EG), wherein an amount of HF is lesser than that of EG. The surface of the semiconductor structure has a nitride layer.

In one embodiment of the present invention according to the method for treating a surface of a semiconductor structure, a ratio of hydrogen fluoride (HF) to ethylene glycol (EG) is about 1:20 to about 1:50.

In one embodiment of the present invention according to the method for treating a surface of a semiconductor structure, a weight percentage of ethylene glycol (EG) is about 1% to about 20%.

In one embodiment according to the method for treating a surface of a semiconductor structure, a weight percentage of hydrogen fluoride (HF) is about 1% to about 50%.

In one embodiment of the present invention according to the method for treating a surface of a semiconductor structure, after applying the first cleaning solution, the method further includes a step of applying to the surface of the semiconductor structure a second cleaning solution containing essentially ammonium hydroxide (NH₄OH).

In one embodiment of the present invention according to the method for treating a surface of a semiconductor structure, the second cleaning solution further includes ethylene glycol (EG), wherein a ratio of ammonium hydroxide (NH₄OH) to ethylene glycol (EG) is about 1:10 to about 1:50 in the second cleaning solution.

In one embodiment of the present invention according to the method for treating a surface of a semiconductor structure, a weight percentage of ammonium hydroxide (NH4OH) is about 10% to about 50%.

In one embodiment of the present invention according to the method for treating a surface of a semiconductor structure, before applying the first cleaning solution, the method further including a step of performing a chemical mechanical polish (CMP) process to expose the nitride layer of the surface of the semiconductor structure.

In one embodiment of the present invention according to the method for treating a surface of a semiconductor structure, the semiconductor structure has at least one deep trench isolation with a width larger than 0.5 um extending downwardly from the surface of the semiconductor structure.

In one embodiment of the present invention according to the method for treating a surface of a semiconductor structure, the semiconductor structure further has at least one shallow trench isolation with a width less than 0.2 um extending downwardly from the surface of the semiconductor structure.

### BRIEF DESCRIPTION OF THE DRAWINGS

The present invention will become more readily apparent to those ordinarily skilled in the art after reviewing the following detailed description and accompanying drawings, in which:

FIG. 1 is a flow chart illustrating a surface treating process;

FIG. 2 schematically illustrates a top view of a semi-finished semiconductor structure for an image sensor;

FIGS. 3A-3E are cross-sectional views of a plurality of processing structures for fabricating an image sensor in accordance with one embodiment of the present invention; and

FIG. 4 schematically illustrates a post CMP cleaner.

### DETAILED DESCRIPTION OF PREFERRED EMBODIMENTS

The present invention will now be described more specifically with reference to the following embodiments. It is to be noted that the following descriptions of preferred embodiments of this invention are presented herein for purpose of illustration and description only. It is not intended to be exhaustive or to be limited to the precise form disclosed.

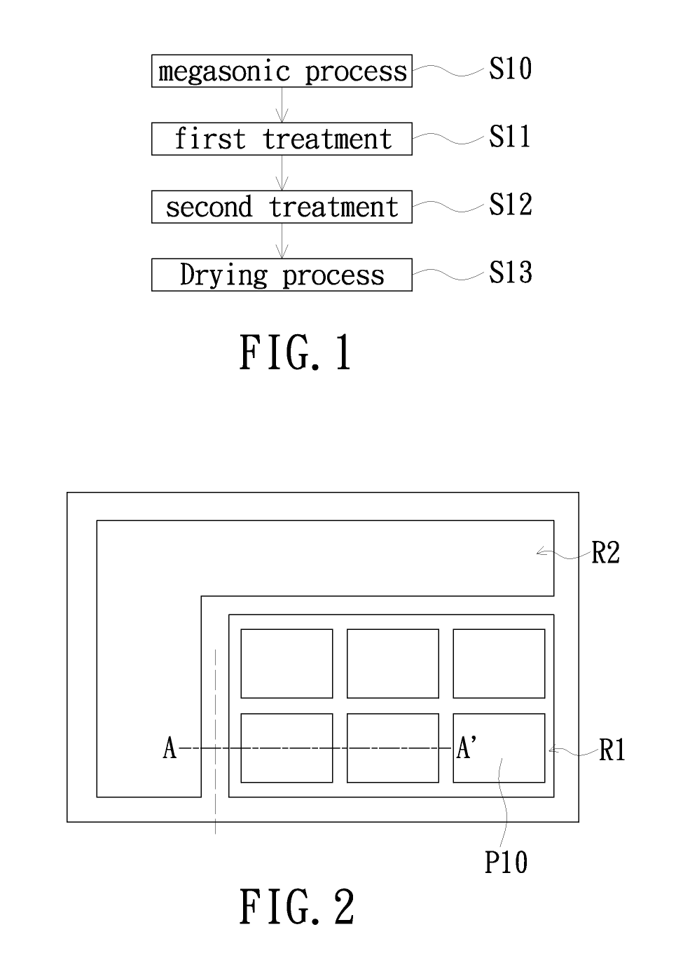

The present invention provides a general surface treating process especially used as a cleaning process in semiconductor manufacture. The surface treating process as shown in FIG. 1, a specimen/wafer with a semiconductor structure may be usually applied in a megasonic process S10, a first treatment S11 with a first cleaning solution, a second treatment S12 with a second cleaning solution, and then a drying process S13. The megasonic process S10 is a type of acoustic process to provide cavitation effect so as to gently remove partial residues on a surface of a semiconductor structure if applied in semiconductor manufacture process. The first treatment S11 and the second treatment S12 are to brush the surface of the semiconductor structure with the first and second cleaning solution, respectively, in order to wash off residues on the surface, and a drying process S13, such as spin dry, is then applied to finish the surface treating process. The second treatment S12 is optional and is performed in cases where particles/residues is found to be remaining on the surface after the first treatment S11. Materials of the surface of a specimen/wafer may include dielectric layer, such as nitride layer, and it is especially easy to suffer fall-on particles/residues after a planarization process in a fabricating process, e.g. chemical mechanical polishing (CMP) in semiconductor manufacturing. In addition, the specimen/wafer may have a plurality of trenches, which may be of all shallow trenches having a width less than 0.2 um, of all deep trenches having a width larger than 0.5 um, or both.

In one of the embodiments of the present invention used in semiconductor manufacturing process, the surface treating process is applied as a post CMP cleaning process. A CMP process is performed to expose a surface of a semiconductor structure, such as a nitride layer, and then the surface treating process starts with the megasonic process S10, then continues with the first treatment S11 and the second treatment S12, and ends up with the drying process S13. Ammonium hydroxide (NH₄OH) is used in the first cleaning solution of the first treatment S11 and dilute hydrogen fluoride (DHF) is used in the second cleaning solution of the second treatment S12. The percentage of residues remained on the surface of the semiconductor structure after the surface treating processes may be about 10% to 30% of the total area of the surface.

In one embodiment of the present invention used in semiconductor manufacturing process, the surface treating process is applied as a post CMP cleaning process. A CMP process is performed to expose a surface of a semiconductor structure, such as a nitride layer, and then the surface treating process starts with the megasonic process S10, then continues with the first treatment S11, and ends up with the drying process S13. Hydrogen fluoride (HF) and ethylene glycol (EG) are used in the first cleaning solution of the first treatment S11. The result achieved without providing the optional second treatment S12 is that residues which were on the substrate surface of the semiconductor structure are almost removed, and the percentage of residues remained on the surface of the semiconductor structure after the surface treating process may be less than 1.5% of the total area of the surface.

In one embodiment of the present invention used in semiconductor manufacturing process, the surface treating process is applied as a post CMP cleaning process. A CMP process is performed to expose a surface of a semiconductor structure, such as a nitride layer, and then the surface treating process starts with the megasonic process S10, then continues with the first treatment S11, the second treatment S12, and ends up with the drying process S13. Hydrogen fluoride (HF) and ethylene glycol (EG) are used in the first cleaning solution of the first treatment S11, and ammonium hydroxide (NH₄OH) is used in the second cleaning solution of the second treatment S12. The result achieved is that residues which were on the surface of the semiconductor structure are almost or all removed, and the percentage of residues remained on the surface of the semiconductor structure after the surface treating process is less than 1.5% of the total area of the surface.

In one other embodiment of the present invention used in semiconductor manufacturing process, the surface treating process is applied as a post CMP cleaning process. A CMP process is performed to expose a surface of a semiconductor structure, such as a nitride layer, and then the surface treating process starts with the megasonic process S10, then the first treatment S11, the second treatment S12, and ends up with the drying process S13. Hydrogen fluoride (HF) and ethylene glycol (EG) are used in the first cleaning solution of the first treatment S11 and ammonium hydroxide (NH₄OH) and ethylene glycol (EG) are used in the second cleaning solution of the second treatment S12. The result achieved is that the residues left on the surface of the semiconductor structure are almost or all removed and the percentage of residues remained on the surface of the semiconductor structure after the treating process is less than 1.5% of the total area of the surface.

In one embodiment, a weight percentage of HF may be about 1% to about 50%; a weight percentage of EG may be about 1% to about 20%; and a weight percentage of NH₄OH may be about 10% to about 50%. An amount of HF is lesser than that of EG in the first cleaning solution of the first treatment S11. In one embodiment, the ratio of HF to EG is about 1:20 to about 1:50 in the first cleaning solution of the first treatment S11. In an embodiment of the present invention, the ratio of HF to EG is about 1:38 in the first cleaning solution of the first treatment S11. In one embodiment, a ratio of NH₄OH to EG is about 1:10 to about 1:50 in the second cleaning solution of the second treatment S12.

The present invention is illustrated in details below. For the purpose of providing a thorough understanding, the surface treating process of the present invention applied in a fabricating process of a complementary metal oxide semiconductor (CMOS) image sensor is used in the following description. However, to one having ordinary skill in the art that the specific detail need not be employed to practice the present invention. In other instances, well-known materials or methods have not been described in detail in order to avoid obscuring the present invention.

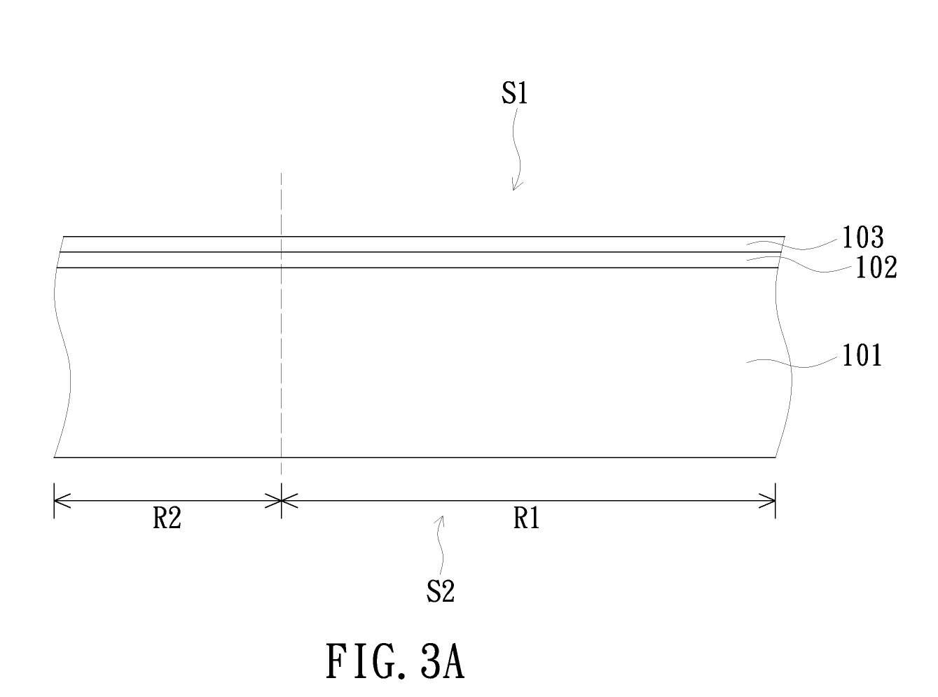

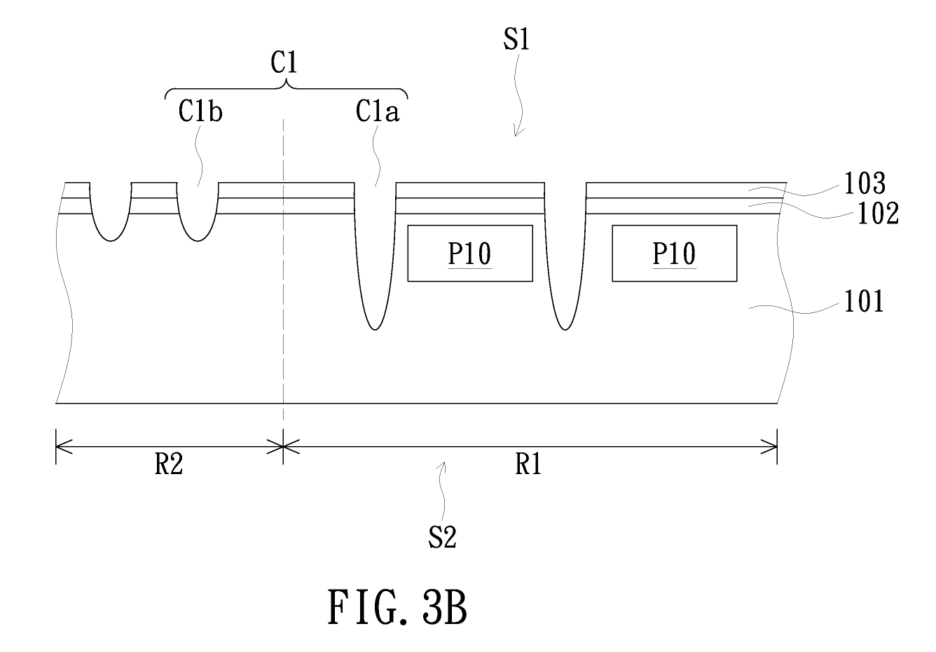

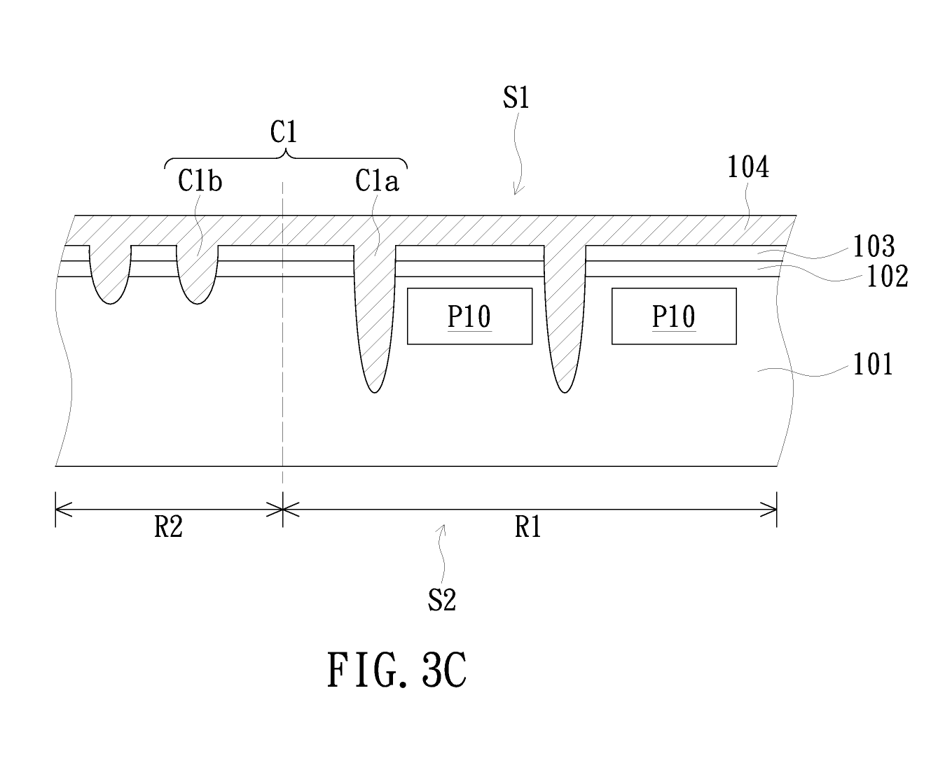

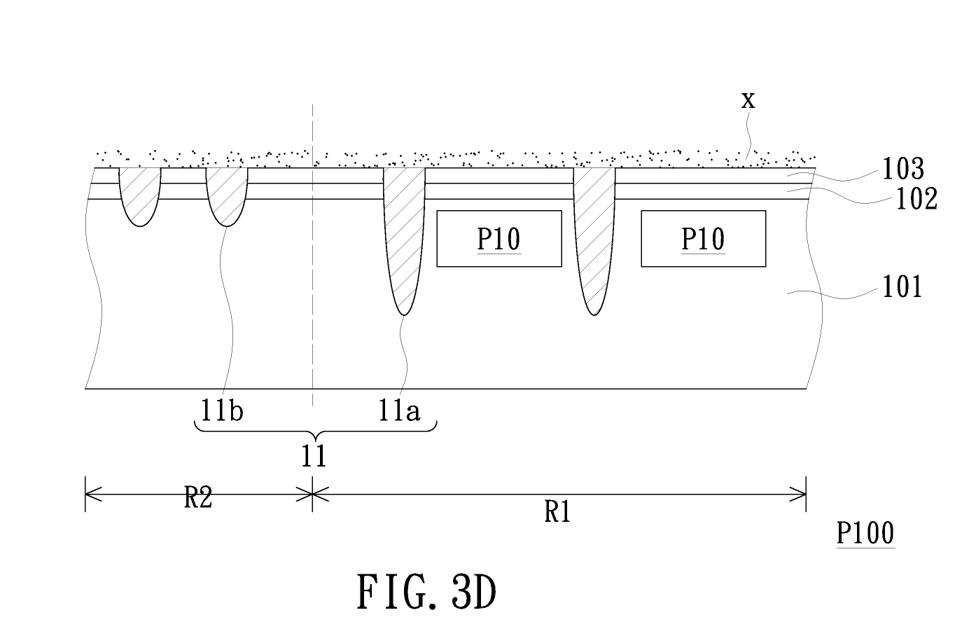

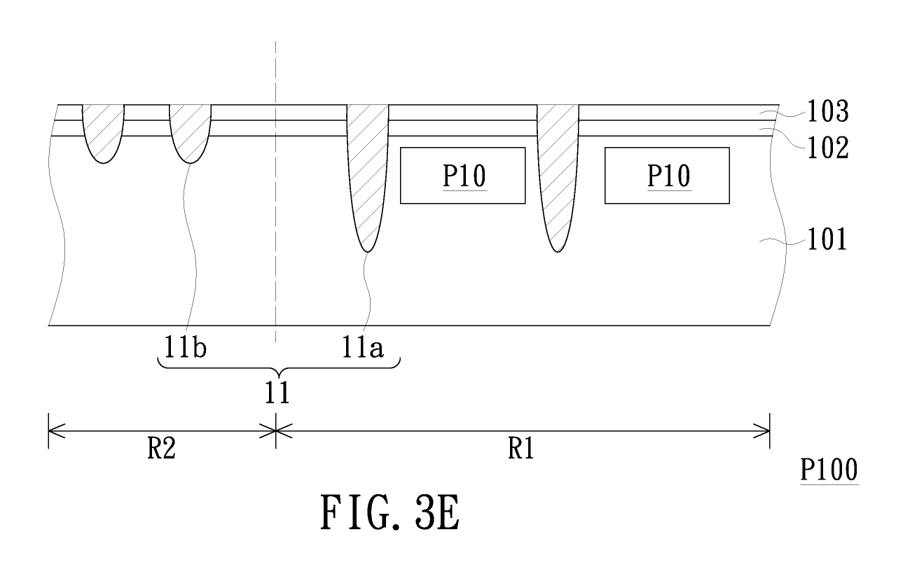

FIG. 2 schematically illustrates a top view of a semi-finished semiconductor structure for an image sensor according to one embodiment of the present invention. FIGS. 3A-3E schematically depict cross-sectional views along line A-A′ shown in FIG. 2 of the semi-finished semiconductor structure for a CMOS image sensor fabricating processing.

Please refer to FIG. 2 and FIG. 3A, a substrate 101 having at least two opposite sides S1 and S2 are provided. Then a pixel region R1 covering most of the substrate 101 and a logic circuit region R2 on a periphery of the substrate 101 are defined. The pixel region R1 essentially includes an array of active zones P10 where pixels are later going to be formed. Next, a nitride layer 103 is formed on the side S1 of the substrate 101 and may cover the pixel region R1 and the logic circuit region R2 completely. The substrate 101 may be made of silicon, and the nitride layer 103 may be formed by chemical vapor deposition (CVD) or any other conventional methods. The substrate 101 may also include a pad oxide layer 102 at the side S1 thereof which the nitride layer 103 may be formed thereon. Then as shown in FIG. 3B, a plurality of cavities C1 may be formed in the substrate 101. More specifically, the nitride layer 103 and the pad oxide layer 102 are patterned by a photolithography process so as to form a hard mask for defining openings of the cavities C1. Then, an etching process is performed to form the cavities C1 extending from the openings of the cavities C1 towards the side S2 of the substrate 101. In one embodiment, the cavities C1 can be formed as all shallow trenches or all deep trenches. In one embodiment of the present invention, the cavities C1 may include deep trenches in the logic circuit region R2 and shallow trenches in the pixel region R1 (not shown). As shown in FIG. 3B in accordance with an embodiment of the present invention, the cavities C1 includes a plurality of deep trenches C1a with a width larger than 0.5 um in the pixel region R1 and a plurality of shallow trenches C1b with a width less than 0.2 um in the logic circuit region R2. Besides, the deep trenches C1a are deeper and wider than the shallow trenches C1b. The deep trenches C1a may be disposed between the active zones P10 which are entirely covered by the patterned nitride layer 103.

As shown in FIG. 3C, a deposition process is performed to fill up the cavities C1, which includes the deep trenches C1a and the shallow trenches C1b in this case, and cover the entire surface of the substrate 101 on the side Si with a dielectric material layer 104. In one embodiment of the present invention, the material of the dielectric material layer 104 may be, but not limited to, silicon oxide.

Please refer to FIG. 3D, a planarization process is performed subsequently to the deposition process to expose the patterned nitride layer 103 and form a plurality of trench isolation structures 11. After the planarization process, top surfaces of the trench isolation structures 11 are coplanar to top surfaces of the patterned nitride layer 103 at the side S1 of the substrate 101. In the illustrated embodiment shown in FIG. 3D, the trench isolation structures 11 include a plurality of deep trench isolations (DTI) 11a in the pixel region R1 and a plurality of shallow trench isolations (STI) 11b in the logic circuit region R2. In other embodiments, the trench isolation structures 11 can be all shallow trench isolations (STI), all deep trench isolations (DTI), or deep trench isolations (DTI) in logic circuit region R2 and shallow trench isolations (STI) in pixel region R1. In one of embodiments of the present invention, the planarization process may be chemical mechanical polishing (CMP). After the planarization process, a semi-finished semiconductor structure P100 having a surface on the side S1 including the patterned nitride layer 103 in the pixel region R1 and the logic circuit region R2 is formed.

After the planarization process, tiny particles or residues X are usually easy to be attached to the patterned nitride layer 103, as shown in FIG. 3D. A surface treating process is then performed in order to remove tiny particles and residues X from the surface of the semi-finished semiconductor structure P100.

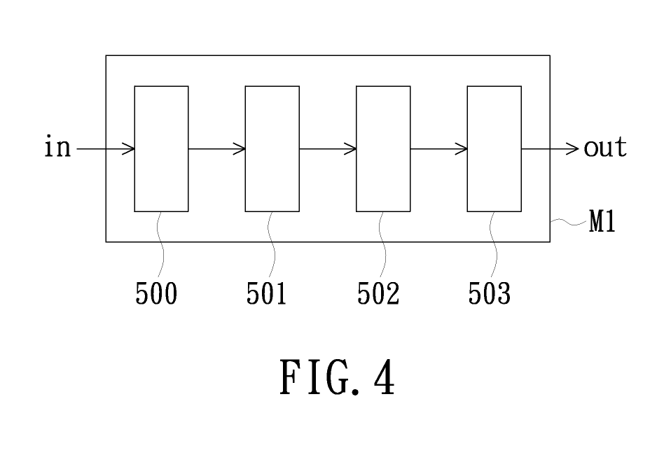

The surface treating process of the present invention is applied in a post CMP cleaner as a post CMP cleaning process in this case of a CMOS image sensor fabricating process. As shown in FIG. 4 according to an embodiment of the present invention, a wafer with the semi-finished semiconductor structure P100 is sent into a post CMP cleaner M1 which usually includes a megasonic unit 500 for performing the megasonic process S10, a first cleaner unit 501 for performing the first treatment S11 using a first cleaning solution, a second cleaner unit 502 for performing the second treatment S12 using a second cleaning solution, and then a dryer 503 for performing the drying process S13. The megasonic unit 500 produces cavitation effect so as to gently remove some of the residues on the wafer surface. The first cleaner unit 501 performs the first treatment S11 by brushing the surface of the wafer with the first cleaning solution in order to wash off residues remained on the surface of the wafer after the megasonic process S10. The second cleaner unit 502 performs the second treatment S12 by brushing the surface of the wafer with the second cleaning solutions in order to wash off residues remained on the surface of the wafer after the first treatment S11. And the dryer 503, such as spin dryer, then performs the drying process S13 to finish the cleaning process. In some embodiments, the second cleaner unit 502 is optional, and the first cleaner unit 501 is capable of performing the first and/or the second treatments S11 and S12 in sequence by only changing/replacing the cleaning solutions in the case of without using the second cleaner unit 502. In addition, the second treatment S12 is also optional and is performed in cases where particles/residues are found to be remaining on the surface of the wafer after the first treatment S11.

For a purpose of clear illustration, abbreviations are used to simplify and shorten the sentences as follows:
*1^{st} (HF+EG)=the first cleaning solution containing hydrogen fluoride (HF) and ethylene glycol (EG)
*2^{nd} (NH₄OH)=the second cleaning solution containing ammonium hydroxide (NH₄OH)
*2^{nd} (NH₄OH+EG)=the second cleaning solution containing ammonium hydroxide (NH₄OH) and ethylene glycol (EG)

In one embodiment of the present invention used in a CMOS image sensor manufacturing process, the surface treating process performed in the cleaner M1 starts with the megasonic process S10 in the megasonic unit 500, then only the first treatment S11 with 1^{st} (HF+EG) in the first cleaner unit 501, and ends up with the drying process S13 in the dryer 503.

In an embodiment of the present invention used in a CMOS image sensor manufacturing process, the surface treating process performed in the cleaner M1 starts with the megasonic process S10 in the megasonic unit 500, then the first treatment S11 with 1^{st} (HF+EG) in the first cleaner unit 501 and the second treatment S12 with 2^{nd} (NH₄OH) in the second cleaner unit 502, and ends up with the drying process S13 in the dryer 503. In another embodiment, the second treatment S12 with 2^{nd} (NH₄OH) is performed in the first cleaner unit 501.

In an embodiment of the present invention used in a CMOS image sensor manufacturing process, the surface treating process performed in the cleaner M1 starts with the megasonic process S10 in the megasonic unit 500, then the first treatment S11 with 1^{st} (HF+EG) in the first cleaner unit 501 and the second treatment S12 with 2^{nd} (NH₄OH+EG) in the second cleaner unit 502, and ends up with the drying process S13 in the dryer 503. In another embodiment, the second treatment S12 with 2^{nd} (NH₄OH+EG) is performed in the first cleaner unit 501.

In one embodiment of the present invention, a weight percentage of HF may be about 1% to about 50%; a weight percentage of EG may be about 1% to about 20%, and a weight percentage of NH₄OH may be about 10% to about 50%. It is to be noted that an amount of HF is lesser than that of EG in the first cleaning solution of the first treatment S11. In one embodiment, the ratio of HF to EG is about 1:20 to about 1:50 in the first cleaning solution of the first treatment S11. In an embodiment of the present invention, the ratio of HF to EG is about 1:38 in the first cleaning solution of the first treatment S11. In one embodiment, a ratio of NH₄OH to EG is about 1:10 to about 1:50 in the second cleaning solution of the second treatment S12.

After the drying process S13, the wafer with the semiconductor structure P100 is outputted from the cleaner M1 and residues are almost or all removed from the surface of the semiconductor structure P100, as shown in FIG. 3E. Thus, the semiconductor structure P100 is well cleaned and adequately prepared for the following fabrication processes of the CMOS image sensor.

In accordance with the aforementioned embodiments of the present invention, a surface treating process and a method for fabricating a CMOS image sensor are provided to ensure of sufficient or adequate particles/residues removal in the treating process. As a result, percentage of particles/residues remained on the surface of the substrate structure is very low and the performance and the yield of the CMOS image sensor can be significantly improved.

While the invention has been described in terms of what is presently considered to be the most practical and preferred embodiments, it is to be understood that the invention needs not be limited to the disclosed embodiment. On the contrary, it is intended to cover various modifications and similar arrangements included within the spirit and scope of the appended claims which are to be accorded with the broadest interpretation so as to encompass all such modifications and similar structures.

What is claimed is:

1. A method for fabricating a CMOS image sensor, comprising steps of:
providing a substrate;
defining a pixel region covering most of said substrate and defining a logic circuit region on a periphery of said substrate;
forming at least one trench in said pixel region;
performing a deposition process to fill said at least one trench and cover said pixel region;
performing a planarization process to expose a surface of said pixel region; and
performing a first treatment on said exposed surface of said pixel region by applying a first cleaning solution comprising hydrogen fluoride (HF) and ethylene glycol (EG), wherein an amount of HF is lesser than that of EG.

2. The method according to claim 1, wherein a ratio of hydrogen fluoride (HF) to ethylene glycol (EG) is about 1:20 to about 1:50.

3. The method according to claim 1, wherein a weight percentage of ethylene glycol (EG) is about 1% to about 20%, and a weight percentage of hydrogen fluoride (HF) is about 1% to about 50%.

4. The method according to claim 1, wherein said trench in said pixel region is a deep trench and has a width larger than 0.5 um.

5. The method according to claim 1, wherein said exposed surface of said pixel region comprises a nitride layer.

6. The method according to claim 1, after said first treatment is performed, further comprising a step of:
performing a second treatment on said exposed surface of said pixel region by applying a second cleaning solution comprising ammonium hydroxide (NH₄OH).

7. The method according to claim 6, wherein a weight percentage of ammonium hydroxide (NH₄OH) is about 10% to about 50%.

8. The method according to claim 6, wherein said second cleaning solution further comprises ethylene glycol (EG), wherein a ratio of ammonium hydroxide (NH₄OH) to ethylene glycol (EG) is about 1:10 to about 1:50 in said second cleaning solution.

9. The method according to claim 1, further comprising a step of:
forming at least one shallow trench in said logic circuit region, wherein
said deposition process is performed to further fill said at least one shallow trench,
said planarization process is performed to further expose a surface of said logic circuit region, and
said first treatment is performed further on said exposed surface of said logic circuit region.

10. The method according to claim 9, wherein said shallow trench has a width less than 0.2 um.

11. A method for treating a surface of a semiconductor structure, comprising a step of:
applying to said surface of said semiconductor structure a first cleaning solution consisting essentially of hydrogen fluoride (HF) and ethylene glycol (EG), wherein an amount of HF is lesser than that of EG, wherein said surface comprises a nitride layer.

12. The method according to claim 11, wherein a ratio of hydrogen fluoride (HF) to ethylene glycol (EG) is about 1:20 to about 1:50.

13. The method according to claim 11, wherein a weight percentage of ethylene glycol (EG) is about 1% to about 20%.

14. The method according to claim 11, wherein a weight percentage of hydrogen fluoride (HF) is about 1% to about 50%.

15. The method according to claim 11, after applying said first cleaning solution, further comprising a step of:
applying to said surface of said semiconductor structure a second cleaning solution consisting essentially of ammonium hydroxide (NH₄OH).

16. The method according to claim 15, wherein said second cleaning solution further comprises ethylene glycol (EG), wherein a ratio of ammonium hydroxide (NH₄OH) to ethylene glycol (EG) is about 1:10 to about 1:50 in said second cleaning solution.

17. The method according to claim 15, wherein a weight percentage of ammonium hydroxide (NH₄OH) is about 10% to about 50%.

18. The method according to claim 11, before applying said first cleaning solution, further comprising a step of:
performing a chemical mechanical polish (CMP) process to expose said nitride layer of said surface of said semiconductor structure.

19. The method according to claim 11, wherein said semiconductor structure comprises at least one deep trench isolation having a width larger than 0.5 um, wherein said deep trench isolation extends downwardly from said surface of said semiconductor structure.

20. The method according to claim 19, wherein said semiconductor structure further comprises at least one shallow trench isolation having a width less than 0.2 um, wherein said shallow trench isolation extends downwardly from said surface of said semiconductor structure.
